(19) United States
(12) Patent Application Publication
(10) Pub. No.: US 2017/0040494 A1
(43) Pub. Date: Feb. 9, 2017

(54) SEMICONDUCTOR LIGHT EMITTING DEVICE AND METHOD OF MANUFACTURING SAME

(71) Applicant: SAMSUNG ELECTRONICS CO., LTD., Suwon-si (KR)

(72) Inventors: Yong Tae GIM, Gunpo-si (KR); Il Ho AHN, Yongin-si (KR); In Bum YANG, Yongin-si (KR); Dong Yeoul LEE, Suwon-si (KR)

(73) Assignee: SAMSUNG ELECTRONICS CO., LTD., Suwon-si (KR)

(21) Appl. No.: 15/228,164

(22) Filed: Aug. 4, 2016

(30) Foreign Application Priority Data
Aug. 4, 2015 (KR) 10-2015-0110186

(51) Int. Cl. H01L 33/38; H01L 33/62; H01L 33/46; H01L 33/42; H01L 33/06; H01L 33/32

(52) U.S. Cl. CPC H01L 33/387; H01L 33/06; H01L 33/32; H01L 33/46; H01L 33/42; H01L 33/62; H01L 2933/0025; H01L 2933/0016

(57) ABSTRACT

A semiconductor light emitting device includes a semiconductor laminate including a first conductive semiconductor layer, a second conductive semiconductor layer, and an active layer disposed between the first conductive semiconductor layer and the second conductive semiconductor layer, the first conductive semiconductor layer and the active layer defining a first trench exposing a first portion of the first conductive semiconductor layer, and a second trench exposing a second portion of the first conductive semiconductor layer, a first finger electrode disposed in the exposed portion of the first conductive semiconductor layer in the first trench, an insulating layer disposed on an internal surface of the second trench, and a second finger electrode disposed on the insulating layer in the second trench and electrically connected to the second conductive semiconductor layer.

### CROSS-REFERENCE TO RELATED APPLICATION

This application claims priority from Korean Patent Application No. 10-2015-0110186, filed on Aug. 4, 2015, in the Korean Intellectual Property Office, the disclosure of which is incorporated herein by reference in its entirety.

### BACKGROUND

Methods and apparatuses consistent with exemplary embodiments to a semiconductor light emitting device and a method of manufacturing the same.

Semiconductor light emitting devices generate light within certain wavelength bands through the recombination of electrons and holes. Because such semiconductor light emitting devices have various benefits, such as a long effective lifespan, low power consumption, excellent initial driving characteristics, and the like, compared to filament-based light sources, demand for semiconductor light emitting devices continues to increase. In particular, group III nitride semiconductors, which are able to emit short-wavelength blue light, have drawn attention.

Recently, improvements in the light emitting efficiency of semiconductor light emitting devices have been actively researched. In particular, various electrode structures have been developed to improve the light emitting efficiency and optical power of semiconductor light emitting devices.

### SUMMARY

An aspect of one or more exemplary embodiments may provide a semiconductor light emitting device having a novel electrode structure which may prevent light emitting efficiency from deteriorating and improve optical power, and a method of manufacturing the same.

According to an aspect of an exemplary embodiment there is provided semiconductor light emitting device including: a semiconductor laminate including a first conductive semiconductor layer, a second conductive semiconductor layer, and an active layer between the first conductive semiconductor layer and the second conductive semiconductor layer, the second conductive semiconductor layer and the active layer defining a first trench exposing a first portion of the first conductive semiconductor layer, and a second trench exposing a second portion of the first conductive semiconductor layer; a first finger electrode disposed on the first portion of the first conductive semiconductor layer in the first trench; an insulating layer disposed on an internal surface of the second trench; and a second finger electrode disposed on the insulating layer in the second trench and electrically connected to the second conductive semiconductor layer.

The semiconductor light emitting device may further include a current spreading layer disposed on the second conductive semiconductor layer and electrically connected to the second finger electrode.

The current spreading layer may extend into the second trench along an upper surface of the insulating layer.

The second finger electrode may be disposed on a portion of the current spreading layer in the second trench.

The first and second trenches may have substantially the same depth.

The second trench may include a plurality of trenches arranged in a first direction.

The second finger electrode may include a curved structure.

The insulating layer may include a distributed bragg reflector (DBR) multi-layer film.

The semiconductor light emitting device may further include an additional insulating layer on an internal side wall of the first trench.

The current spreading layer may be substantially disposed on an entire region of an upper surface of the second conductive semiconductor layer.

The current spreading layer may include a transparent electrode layer.

The current spreading layer may include at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎ MgOₓ, 0≦x≦1).

The semiconductor light emitting device may further include a third finger electrode.

The semiconductor light emitting device may further include a first electrode pad electrically connected to the first finger electrode and a second electrode pad electrically connected to the second finger electrode.

The semiconductor light emitting device may further include an insulating portion covering a surface of the semiconductor laminate on which the first and second finger electrodes are disposed, the insulating portion comprising a first via connected to the first finger electrode and a second via connected to the second finger electrode, the first and second electrode pads may be disposed on the insulating portion and the first electrode pad may be connected to the first finger electrode through the first via, and the second electrode pad may be connected to the second finger electrode through the second via.

According to an aspect of another exemplary embodiment, there is provided a semiconductor light emitting device including: a semiconductor laminate comprising a first conductive semiconductor layer, a second conductive semiconductor layer, and an active layer between the first conductive semiconductor layer and the second conductive semiconductor layer, the second conductive semiconductor layer and the active layer defining a first trench exposing a first portion of the first conductive semiconductor layer, and a second trench exposing a second portion of the first conductive semiconductor layer; a first insulating layer disposed on an internal side wall of the first trench; a first finger electrode disposed on the first portion of the first conductive semiconductor layer in the first trench; a second insulating layer disposed on an internal surface of the second trench; a current spreading layer disposed on the second conductive semiconductor layer and extending into the second trench along the second insulating layer; and a second finger electrode disposed on a portion of the current spreading layer in the second trench.

The semiconductor light emitting device may further include a first electrode pad electrically connected to the first finger electrode and a second electrode pad electrically connected to the second finger electrode, the first electrode pad may be disposed on the portion of the first conductive semiconductor layer in the first trench, and the second electrode pad may be disposed on the second conductive semiconductor layer.

The semiconductor light emitting device may further include an additional insulating layer disposed between the second electrode pad and the second conductive semiconductor layer.

According to an aspect of still another exemplary embodiment, there is provided a method of manufacturing a semiconductor light emitting device, the method including: forming a semiconductor laminate by sequentially growing a first conductive semiconductor layer, an active layer, and a second conductive semiconductor layer on a substrate; forming a first trench and a second trench in the semiconductor laminate, the first and second trenches passing through the second conductive semiconductor layer and the active layer to expose a first portion and a second portion of the first conductive semiconductor layer; forming an insulating layer on an internal surface of the second trench; forming a current spreading layer on the second conductive semiconductor layer to extend to a portion of the insulating layer in the second trench; forming a first finger electrode in the first exposed portion of the first conductive semiconductor layer; and forming a second finger electrode on a portion of the current spreading layer in the second trench.

The first trench and the second trench may be formed by a single etching process.

The forming of the insulating layer may include forming an additional insulating layer on an internal side wall of the first trench.

The forming of the first finger electrode and the forming of the second finger electrode may be performed simultaneously.

According to an aspect of yet another exemplary embodiment, there is provided a semiconductor light emitting device including: a first conductive semiconductor layer, a second conductive semiconductor layer, and an active layer between the first conductive semiconductor layer and the second conductive semiconductor layer, the second conductive semiconductor layer and the active layer defining a plurality of first trenches exposing a plurality of first portions of the first conductive semiconductor layer, and a plurality of second trenches exposing a plurality of second portions of the; a plurality of first finger electrodes respectively disposed on the plurality of first portions within the plurality of first trenches; a plurality of insulating portions disposed on the plurality of second portions within the plurality of second trenches; and a plurality of second finger electrodes respectively disposed on the plurality of insulating portions.

The semiconductor light emitting device may further include a current spreading layer disposed on the second conductive semiconductor layer and electrically connected to one of the plurality of second finger electrodes.

The current spreading layer may extend into one of the plurality of second trenches.

### BRIEF DESCRIPTION OF DRAWINGS

The above and other aspects will be more clearly understood from the following detailed description taken in conjunction with the accompanying drawings, in which:

FIG. 1 is a plan view schematically illustrating a semiconductor light emitting device according to an exemplary embodiment;

FIG. 2 is a schematic cross-sectional view taken along line X-X′ of the semiconductor light emitting device illustrated in FIG. 1 according to an exemplary embodiment;

FIG. 3 is a schematic cross-sectional view taken along line Y-Y′ of the semiconductor light emitting device illustrated in FIG. 1 according to an exemplary embodiment;

FIGS. 4A through 4E are cross-sectional views of a process of manufacturing a semiconductor light emitting device according to one or more exemplary embodiments;

FIG. 5 is a side cross-sectional view schematically illustrating a semiconductor light emitting device according to an exemplary embodiment;

FIG. 6 is a schematic cross-sectional view taken along line X-X′ of the semiconductor light emitting device illustrated in FIG. 5 according to an exemplary embodiment;

FIG. 7 is a schematic cross-sectional view taken along line Y-Y′ of the semiconductor light emitting device illustrated in FIG. 5 according to an exemplary embodiment;

FIG. 8 is a side cross-sectional view schematically illustrating a semiconductor light emitting device according to an exemplary embodiment;

FIG. 9 is a schematic cross-sectional view taken along line X1-X1′ of the semiconductor light emitting device illustrated in FIG. 8 according to an exemplary embodiment;

FIG. 10 is a schematic cross-sectional view taken along line X2-X2′ of the semiconductor light emitting device illustrated in FIG. 8 according to an exemplary embodiment;

FIG. 11 is a schematic cross-sectional view taken along line Y-Y′ of the semiconductor light emitting device illustrated in FIG. 8 according to an exemplary embodiment;

FIG. 12 is a side cross-sectional view illustrating a package employing the semiconductor light emitting device illustrated in FIG. 1 according to an exemplary embodiment;

FIG. 13 is a side cross-sectional view illustrating a package employing the semiconductor light emitting device illustrated in FIG. 8 according to an exemplary embodiment;

FIG. 14 is a perspective view of a backlight unit employing a semiconductor light emitting device according to an exemplary embodiment;

FIG. 15 is a cross-sectional view of a direct type backlight unit employing a semiconductor light emitting device according to an exemplary embodiment;

FIG. 16 is an exploded perspective view of a display device employing a semiconductor light emitting device according to an exemplary embodiment; and

FIG. 17 is an exploded perspective view of a lighting device employing a semiconductor light emitting device according to an exemplary embodiment.

### DETAILED DESCRIPTION

Hereinafter, exemplary embodiments will be described in detail with reference to the accompanying drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element, as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Hereinafter, exemplary embodiments will be described with reference to schematic views. In the drawings, for example, due to manufacturing techniques and/or tolerances, modifications of the shape shown may be estimated. Thus, exemplary embodiments should not be construed as being limited to the particular shapes of regions shown herein, for example, to include a change in shape results in manufacturing. The following exemplary embodiments may also be constituted by one or a combination thereof.

The exemplary embodiments described below may have a variety of configurations and propose only a required configuration herein, but are not limited thereto.

Meanwhile, the term “exemplary embodiment” used throughout this specification does not refer to the same exemplary embodiment, and the term is provided to emphasize a particular feature or characteristic different from another exemplary embodiment. However, exemplary embodiments provided hereinafter are considered to be able to be implemented by being combined in whole or in part with one another. For example, one element described in a particular exemplary embodiment, even if it is not described in another exemplary embodiment, may be understood as a description related to another exemplary embodiment, unless an opposite or contradictory description is provided therein.

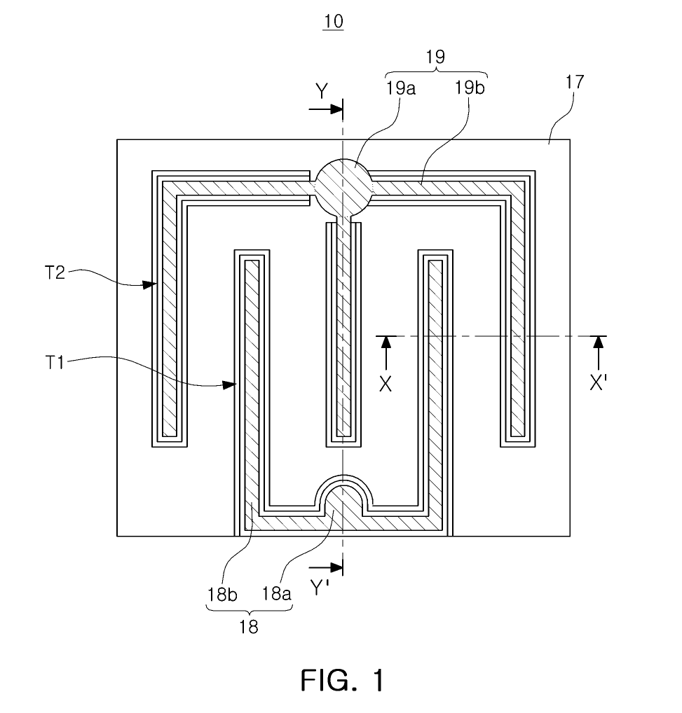

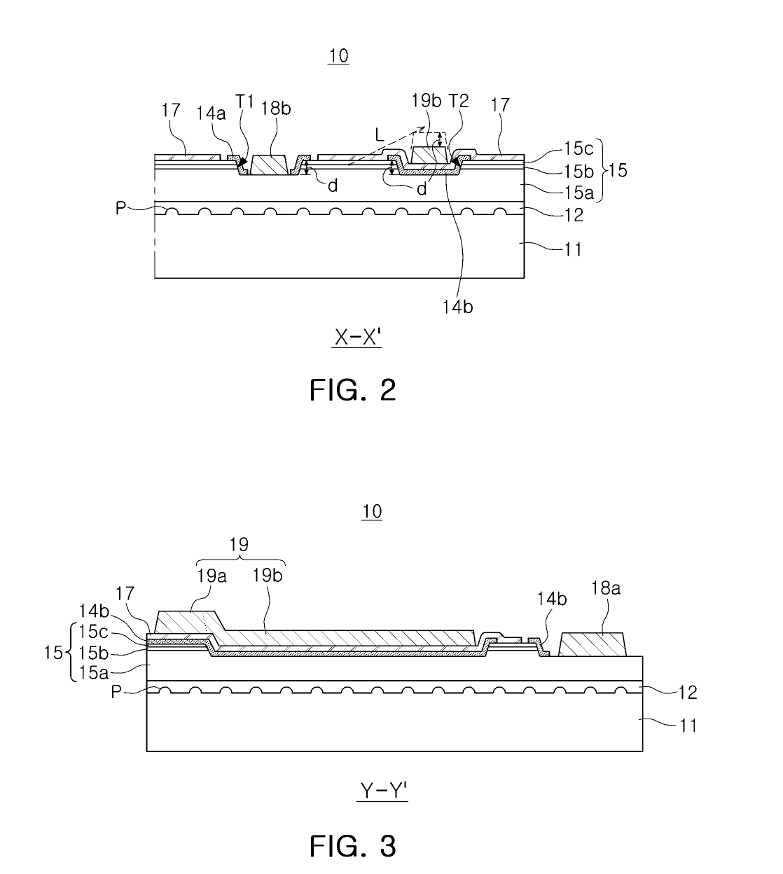

FIG. 1 is a plan view schematically illustrating a semiconductor light emitting device according to an exemplary embodiment. FIGS. 2 and 3 are schematic cross-sectional views respectively taken along lines X-X′ and Y-Y′ of the semiconductor light emitting device illustrated in FIG. 1.

Referring to FIGS. 1-3, a semiconductor light emitting device 10 according to an exemplary embodiment may include a substrate 11 and a semiconductor laminate 15 disposed on the substrate 11.

The semiconductor laminate 15 may include a first conductive semiconductor layer 15a, an active layer 15b, and a second conductive semiconductor layer 15c. A buffer layer 12 may be provided between the substrate 11 and the first conductive semiconductor layer 15a.

The substrate 11 may be an insulating, conductive, or semiconductor substrate. For example, the substrate 11 may be sapphire, SiC, Si, MgAl₂O₄, MgO, LiAlO₂, LiGaO₂, or GaN. An uneven portion P may be formed on an upper surface of the substrate 11. The uneven portion P may increase optical extraction efficiency and improve quality of a single crystal being grown. The uneven portion P employed in the exemplary embodiment may be a protrusion having a hemispherical shape or a non-flat structure having various other shapes.

The buffer layer 12 may be InₓAl_{y}Ga_{1-x-y}N (0≦x≦1, 0≦y≦1). For example, the buffer layer 12 may be AN, AlGaN, or InGaN. If necessary, the buffer layer 12 may be formed by combining a plurality of layers or gradually changing compositions thereof.

The first conductive semiconductor layer 15a may be a nitride semiconductor layer satisfying n-type AlₓIn_{y}Ga_{1-x-y}N (0≦x≦1, 0≦y≦1, 0≦x+y≦1), and an n-type impurity may be Si. For example, the first conductive semiconductor layer 15a may be n-type GaN. The second conductive semiconductor layer 15c may be a nitride semiconductor layer satisfying p-type AlₓIn_{y}Ga_{1-x-y}N, and a p-type impurity may be Mg. For example, the second conductive semiconductor layer 15c may be p-type AlGaN/GaN. The active layer 15b may have a multiple quantum well (MQW) structure in which quantum well layers and quantum barrier layers are alternately stacked with each other. For example, in the case of using a nitride semiconductor, the active layer 15b may have a GaN/InGaN MQW structure.

A first electrode 18 and a second electrode 19 may include a first electrode pad 18a and a second electrode pad 19a, and a plurality of first finger electrodes 18b and a plurality of second finger electrodes 19b extending therefrom, respectively. According to the exemplary embodiment, the plurality of first and second finger electrodes 18b and 19b may be arranged to intersect each other. According to an exemplary embodiment, there may be one of first and second electrode pad 18a and 19a. Unlike the illustrated exemplary embodiment, there may be a plurality of at least one of the first and second electrode pads 18a and 19a.

The semiconductor laminate 15 may include the first and second trenches T1 and T2. The first and second trenches T1 and T2 may penetrate through the second conductive semiconductor layer 15c and the active layer 15b to allow portions of the first conductive semiconductor layer 15a to be exposed. The first and second trenches T1 and T2 may have substantially the same depth d. Bottom surfaces of the first and second trenches T1 and T2 may provide portions in which the first and second finger electrodes 18b and 19b are to be formed, respectively.

The first finger electrodes 18b may be disposed on the bottom surface of the first trench T1 to be connected to the exposed portion of the first conductive semiconductor layer 15a. A first insulating layer 14a may be disposed on an internal side wall of the first trench T1. Similar to the first finger electrodes 18b, the second finger electrodes 19b may be disposed on the bottom surface of the second trench T2. The second finger electrodes 19b may not be connected to the first conductive semiconductor layer 15a by a second insulating layer 14b disposed on an internal surface of the second trench T2.

According to the illustrated exemplary embodiment, the second finger electrodes 19b may be connected to a current spreading layer 17. As illustrated in FIGS. 2 and 3, the current spreading layer 17 may extend into the second trench T2 along the second insulating layer 14b. The current spreading layer 17 may extend to the bottom surface of the second trench T2, and the second finger electrodes 19b may be disposed in an extended portion of the current spreading layer 17. For the extension of the current spreading layer 17, the second insulating layer 14b may extend to the bottom surface of the second trench T2 and an internal side wall thereof.

As such, disposing the second finger electrodes 19b into the second trench T2 may allow the bottom surface of the second finger electrodes 19b to be disposed at the depth d of the second trench T2. Resultantly, it is less likely to contact light L emitted from the active layer 15b, thereby increasing optical extraction efficiency. Moreover, light emitting efficiency may be improved in other effective light emitting regions by removing an active layer portion that does not contribute to light emitting substantially by the formation of the second trench T2.

According to an exemplary embodiment, as illustrated in FIG. 3, the first electrode pad 18a may be disposed in the exposed portion of the first conductive semiconductor layer 15a in the first trench T1. The second electrode pad 19a may be disposed on the second conductive semiconductor layer 15c. The second insulating layer 14b may extend between the second electrode pad 19a and the second conductive semiconductor layer 15c. In this arrangement, a current spreading effect through the current spreading layer 17 may be improved. Unlike the illustrated exemplary embodiment, the second electrode pad 19a may be disposed in the second trench T2 similarly to the second finger electrodes 19b.

According to an exemplary embodiment, the current spreading layer 17, such as ITO, may be disposed on the second conductive semiconductor layer 15c, but the current spreading layer 17 may not be employed. In this case, an electrical connection between the second finger electrodes 19b and the second conductive semiconductor layer 15c may be implemented by additionally providing at least one sub-electrode extending from the second finger electrodes 19b located in the second trench T2 to an upper surface of the second conductive semiconductor layer 15c. The second finger electrodes 19b located in the second trench T2 may be directly disposed on the second insulating layer 14b.

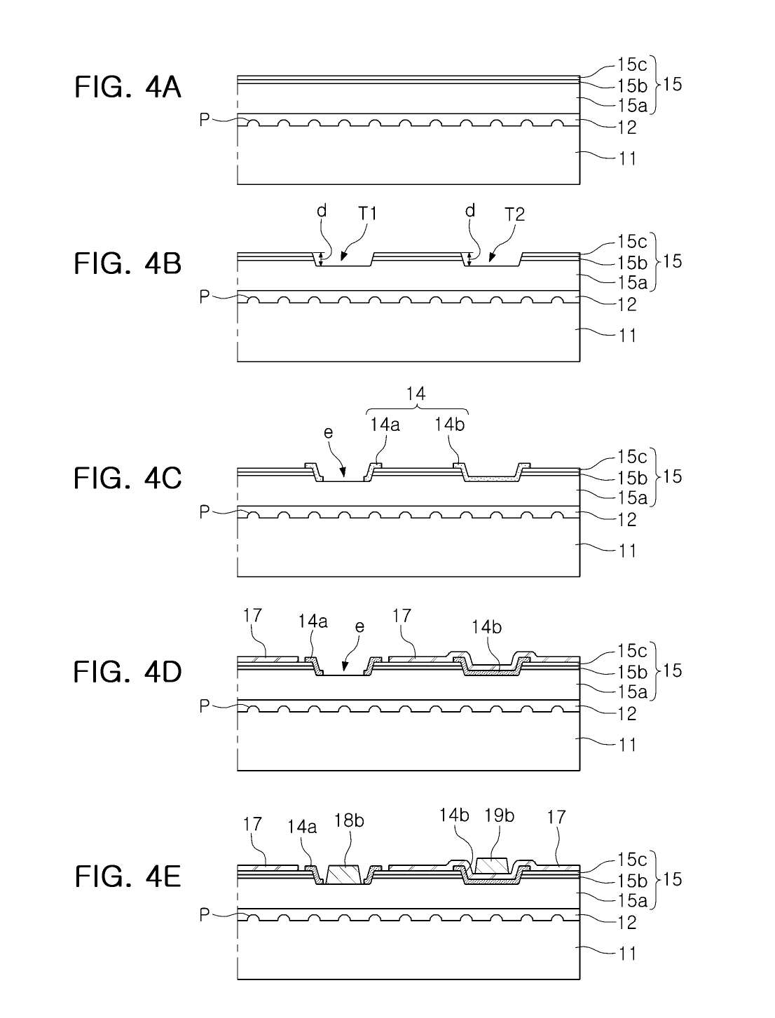

FIGS. 4A through 4E are cross-sectional views of primary processes for describing a process of manufacturing a semiconductor light emitting device according to an exemplary embodiment.

As illustrated in FIG. 4A, the buffer layer 12 may be formed on the substrate 11, and the semiconductor laminate 15 for the light emitting device may be formed on the buffer layer 12.

The semiconductor laminate 15 may include the first conductive semiconductor layer 15a, the active layer 15b, and the second conductive semiconductor layer 15c, and may be the nitride semiconductor described above. The semiconductor laminate 15 may be grown on the substrate 11 using processes, such as metalorganic chemical vapour deposition (MOCVD), molecular beam epitaxy (MBE), and hydride vapour phase epitaxy (HVPE).

As illustrated in FIG. 4B, the first and second trenches T1 and T2 may be formed in the semiconductor laminate 15 such that portions of the first conductive semiconductor layer 15a may be exposed.

This process may be implemented by an etching process of partially removing the second conductive semiconductor layer 15c and the active layer 15b. The second trench T2 may be formed together with the first trench T1 by the same etching process used to form the first trench T1. The first and second trenches T1 and T2 may have substantially the same depth d. The portions of the first conductive semiconductor layer 15a exposed by the first and second trenches T1 and T2 may be provided as regions in which the first and second finger electrodes are to be formed.

As illustrated in FIG. 4C, an insulating layer 14 may be formed on the semiconductor laminate 15 in which the first and second trenches T1 and T2 are formed.

The insulating layer 14 formed in this process may be deposited on the entire region of surfaces in which the first and second trenches T1 and T2 are formed, and then selectively removing portions of the insulating layer 14. Depending on the shapes of the first and second trenches T1 and T2, the insulating layer 14 may be shaped differently. As illustrated in FIG. 4C, the first insulating layer 14a related to the first trench T1 may be formed on the internal side wall of the first trench T1, and may have an opening e in a bottom surface of the first insulating layer 14a to allow a portion of the first conductive semiconductor layer 15a to be exposed. In addition, the second insulating layer 14b related to the second trench T2 may be formed on the side wall and bottom surface of the second trench T2. The current spreading layer 17 to be formed in a subsequent process by this arrangement of the second insulating layer 14b may extend into the second trench T2. The first and second insulating layers 14a and 14b may be formed by substantially the same process. The first and second insulating layers 14a and 14b may be connected to each other on edges of the semiconductor laminate to be integrated with each other. The first and second insulating layers 14a and 14b may be, for example, SiO₂ or SiN. If necessary, the insulating layer 14 may be a distributed bragg reflector (DBR) multi-layer film in which dielectric films having different refractive indexes are alternately stacked. Employing the insulating layer 14 as a DBR multi-layer film structure may further increase optical extraction efficiency.

As illustrated in FIG. 4D, the current spreading layer 17 may be formed on the second conductive semiconductor layer 15b to extend into the second trench T2.

As described above, the current spreading layer 17 formed in this process may extend into the second trench T2 along the second insulating layer 14b. The current spreading layer 17 may come in ohmic contact with the second conductive semiconductor layer 15c, and may uniformly disperse current delivered through a second electrode to the second conductive semiconductor layer 15c. The current spreading layer 17 may be formed over a substantially entire region of the upper surface of the second conductive semiconductor layer 15c.

The current spreading layer 17 may be a transparent conductive oxide. For example, the current spreading layer 17 may be a light transmitting conductive oxide, such as ITO, ZITO, ZIO, GIO, ZTO, FTO, AZO, GZO, In₄Sn₃O₁₂ or Zn₍₁₋ₓ₎MgₓO (0≦x≦1). The light transmitting conductive oxide may be subject to an additional thermal treatment process (e.g., 500° C. or more) after a deposition process to obtain a desired electrical/optical characteristic.

As illustrated in FIG. 4E, the first and second finger electrodes 18b and 19b may be formed.

In this process, the first finger electrode 18b may be formed in the exposed portion e of the first conductive semiconductor layer 15a, and the second finger electrode 19b may be formed on a portion of the current spreading layer 17 located in the second trench T2. The second finger electrode 19b may be located at a relatively low level through the second trench T2 and connected to the second conductive semiconductor layer 15c by an extended portion of the current spreading layer 17.

For example, the first and second finger electrodes 18b and 19b may contain materials, such as Ag, Ni, Al, Rh, Pd, Jr, Ru, Mg, Zn, Pt, and Au, respectively, and may be employed as a structure having a single layer or two or more layers. Although not limited thereto, the first and second finger electrodes may be formed by substantially the same electrode forming process and of substantially the same electrode material.

In addition, the first and second electrode pads 18a and 19b may be formed together in the process of forming the first and second finger electrodes 18b and 19b. If necessary, the first and second electrode pads 18a and 19a may be formed by depositing a bonding metal, such as Au, Sn or Au/Sn, using a separate process.

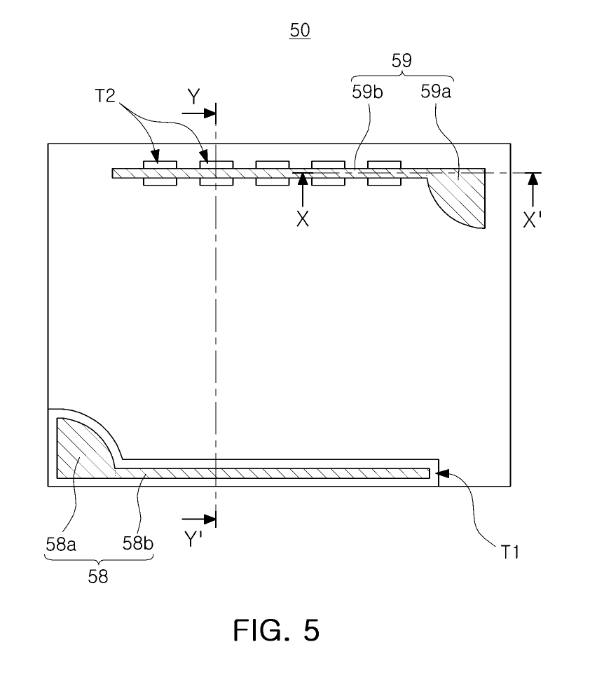

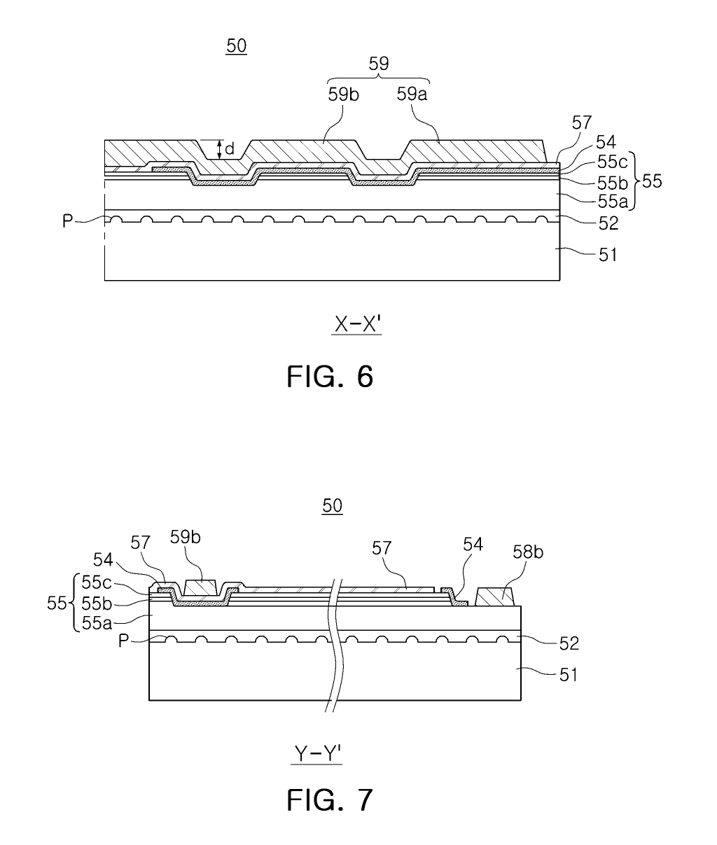

FIG. 5 is a plan view schematically illustrating a semiconductor light emitting device according to an exemplary embodiment. FIGS. 6 and 7 are schematic cross-sectional views respectively taken along lines X-X′ and Y-Y′ of the semiconductor light emitting device illustrated in FIG. 5.

Referring to FIGS. 5 and 6, a semiconductor light emitting device 50 according to an exemplary embodiment may include a substrate 51 and a semiconductor laminate 55 disposed on the substrate 51.

The semiconductor laminate 55 may include a first conductive semiconductor layer 55a, an active layer 55b, and a second conductive semiconductor layer 55c. A buffer layer 52 may be provided between the substrate 51 and the first conductive semiconductor layer 55a. It may be understood that, unless particularly otherwise noted, the components employed in this exemplary embodiment are identical or similar to the components described in previous exemplary embodiments.

A first electrode 58 and a second electrode 59 may include a first electrode pad 58a and a second electrode pad 59a, and a first finger electrode 58b and a second finger electrode 59b extending therefrom, respectively. According to an exemplary embodiment, unlike the previous exemplary embodiments, the first and second finger electrodes 58b and 59b may be employed in the first and second electrode pads 58a and 59a, respectively, and may be disposed adjacently to opposing sides, respectively.

The semiconductor laminate 55 may include a first trench T1 for the first finger electrode 58b and a second trench T2 for the second finger electrode 59b. The first and second trenches T1 and T2 may pass through the second conductive semiconductor layer 55c and the active layer 55b to allow portions of the first conductive semiconductor layer 55a to be exposed. According to an exemplary embodiment, the second trench T2 may be employed in plural, and the plurality of second trenches T2 may be arranged in a length direction of the second finger electrode 59b.

The second finger electrode 59b may be disposed along the second trenches T2 and an upper surface of the second conductive semiconductor layer 55c between the second trenches T2. Thus, the second finger electrode 59b may have a curved shape as illustrated in FIG. 6. As illustrated in FIG. 7, portions of an insulating layer 54 provided on the first trench T1 may open portions of the first conductive semiconductor layer 55a. Thus, the first finger electrode 58b may be disposed on a bottom surface of the first trench T1 to be connected to the open portions of the first conductive semiconductor layer 55a.

Referring to FIG. 6, the insulating layer 54 may be disposed on internal surfaces of the second trenches T2 so that the first conductive semiconductor layer 55a and the active layer 55b may not be exposed. Thus, even when the second finger electrode 59b is formed on the internal surfaces of the plurality of second trenches T2, the second finger electrode 59b may be prevented from being undesirably connected to the first conductive semiconductor layer 55a and the active layer 55b by the insulating layer 54.

According to an exemplary embodiment, a current spreading layer 57 may be formed on the upper surface of the second conductive semiconductor layer 55c and the insides of the second trenches T2. The second finger electrode 59b may be connected to the current spreading layer 57 even in the second trenches T2. When the plurality of second trenches T2 are arranged at a predetermined interval, the second finger electrode 59b may be connected to a portion of the current spreading layer 57 between the second trenches T2 without extending the current spreading layer 57 into the second trenches T2.

According to an exemplary embodiment, disposing the second finger electrode 59b along the plurality of second trenches T2 may allow the second finger electrode 59b to be disposed at a relatively low level as a depth d of the second trenches T2, thereby improving optical extraction efficiency.

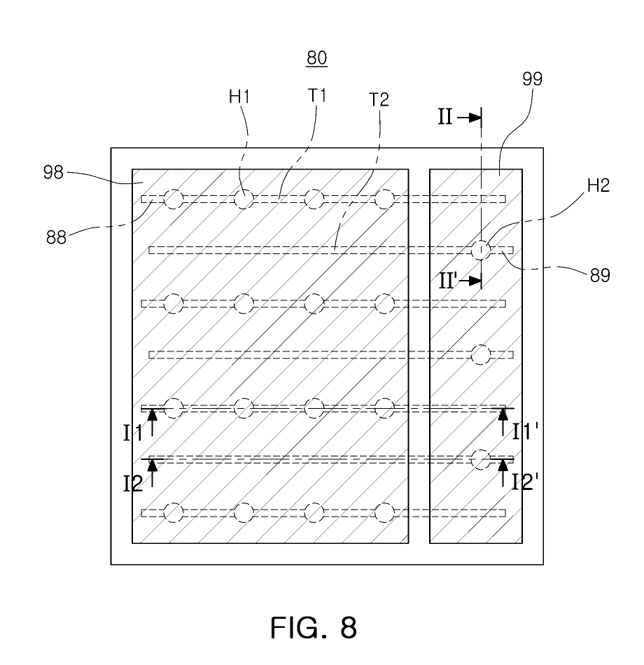

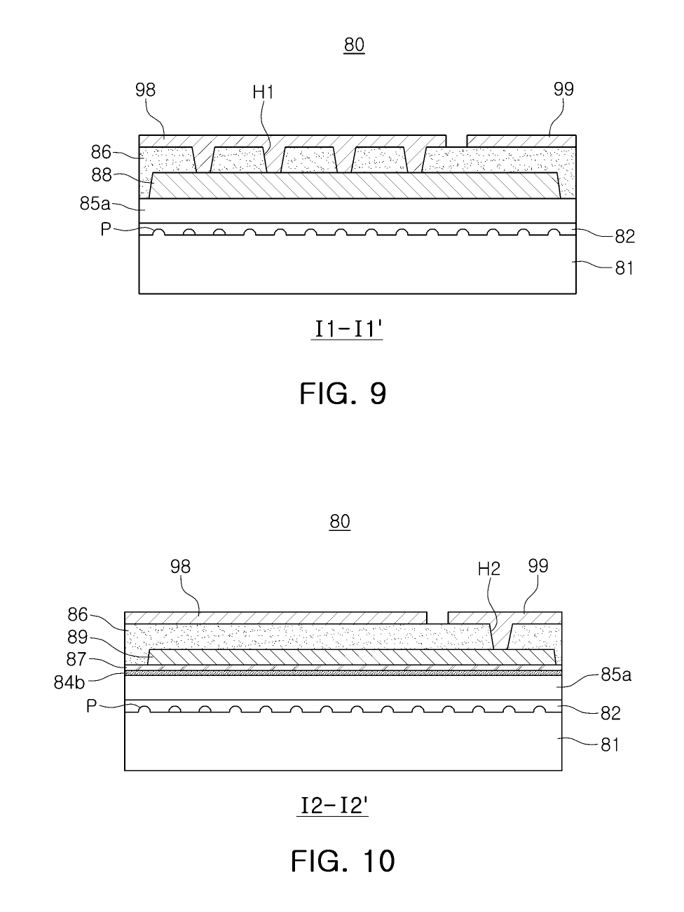

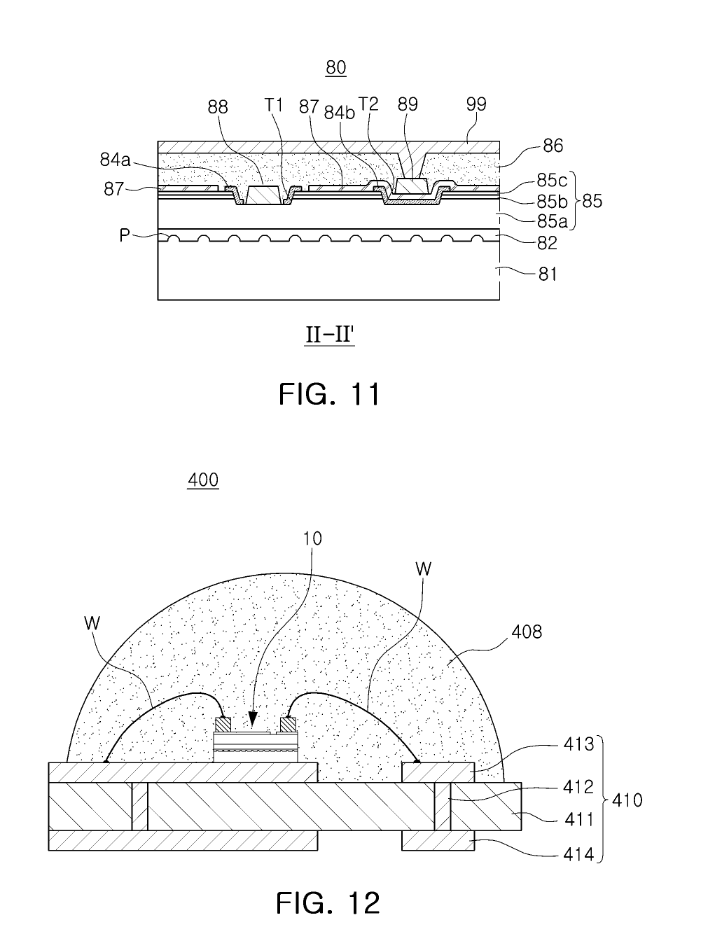

FIG. 8 is a side cross-sectional view schematically illustrating a semiconductor light emitting device having a flip chip structure according to an exemplary embodiment. FIGS. 9 and 10 are schematic cross-sectional views respectively taken along lines X1-X1′ and X2-X2′ of the semiconductor light emitting device illustrated in FIG. 8, and FIG. 11 is a schematic cross-sectional view taken along line Y-Y′ of the semiconductor light emitting device illustrated in FIG. 8.

Referring to FIGS. 8 and 11, a semiconductor light emitting device 80 according to an exemplary embodiment may include a substrate 81 and a semiconductor laminate 85 disposed on the substrate 81.

The semiconductor laminate 85 may include a first conductive semiconductor layer 85a, an active layer 85b, and a second conductive semiconductor layer 85c. A buffer layer 82 may be provided between the substrate 81 and the first conductive semiconductor layer 85a. It may be understood that, unless particularly otherwise noted, the components employed in this exemplary embodiment are identical or similar to the components described in previous exemplary embodiments.

According to an exemplary embodiment, a plurality of first finger electrodes 88 and a plurality of second finger electrodes 89 may be arranged to intersect each other. As illustrated in FIG. 11, the semiconductor laminate 85 may include first trenches T1 for the first finger electrodes 88 and second trenches T2 for the second finger electrodes 89. According to an exemplary embodiment, unlike the previous exemplary embodiments, the second trenches T2 and the first trenches T1 may not provide separate portions for electrode pads 98 and 99.

As illustrated in FIGS. 9 and 11, an insulating layer 84a provided on the first trench T1 may allow a portion of the first conductive semiconductor layer 85a to be exposed to a bottom surface of the insulating layer 84a. The first finger electrode 88 may be connected to the exposed portion of the first conductive semiconductor layer 85a.

Referring to FIGS. 10 and 11, the insulating layer 84b formed on the second trench T2 may insulate internal surfaces of the second trench T2, and the current spreading layer 87 may extend into the second trench T2 along a surface of the insulating layer 84b. The second finger electrode 89 may be disposed on a portion of the current spreading layer 87 in the second trench T2.

An insulating portion 86 may cover a surface of the semiconductor laminate 85 on which the first and second finger electrodes 88 and 89 are disposed. The insulating portion 86 may also have a first via H1 and a second via H2 respectively connected to the first and second finger electrodes 88 and 89. According to the illustrated exemplary embodiment, there are a plurality of first vias H1, and a single second via H2, this is merely an example and the number of vias is not limited thereto. According to various exemplary embodiments, there may be one or more first vias H1 and one or more second vias H2. A first electrode pad 98 and a second electrode pad 99 may be disposed on the insulating portion 86. The first and second electrode pads 98 and 99 may be connected to the first and second finger electrodes 88 and 89 through the first and second vias H1 and H2, respectively.

According to an exemplary embodiment, at least one of the insulating layer 84 and the insulating portion 86 may be a DBR multi-layer film. For example, dielectric layers having different refractive indexes may be alternately stacked for use as a high reflection layer insulating structure.

As such, by disposing the second finger electrode 89 along the second trench T2, even in the flip chip structure, allows the second finger electrode 89 to be disposed at a relatively low level as the depth of the second trench T2, thereby improving optical extraction efficiency.

The semiconductor light emitting device according to the aforementioned exemplary embodiments may be employed as a light source in various types of applications.

FIG. 12 is a cross-sectional view illustrating a package 400 employing a semiconductor light emitting device 10 illustrated in FIG. 1.

The semiconductor light emitting device package 400 illustrated in FIG. 12 may include the semiconductor light emitting device 10 illustrated in FIG. 1, a mounting substrate 410, and an encapsulant 408. The semiconductor light emitting device 10 may be disposed on the mounting substrate 410 to be electrically connected to the mounting substrate 410 through a wire W. The mounting substrate 410 may include a substrate body 411, an upper electrode 413, a lower electrode 414, and a through electrode 412 connecting the upper electrode 413 to the lower electrode 414. The mounting substrate 410 may be provided as substrates, such as a PCB, an MCPCB, an MPCB, and an FPCB, and a structure of the mounting substrate 410 may be applied in various forms.

The encapsulant 408 may have a dome-shaped lens having a convex upper surface, and may adjust an orientation angle of light emitted by introducing a different structure.

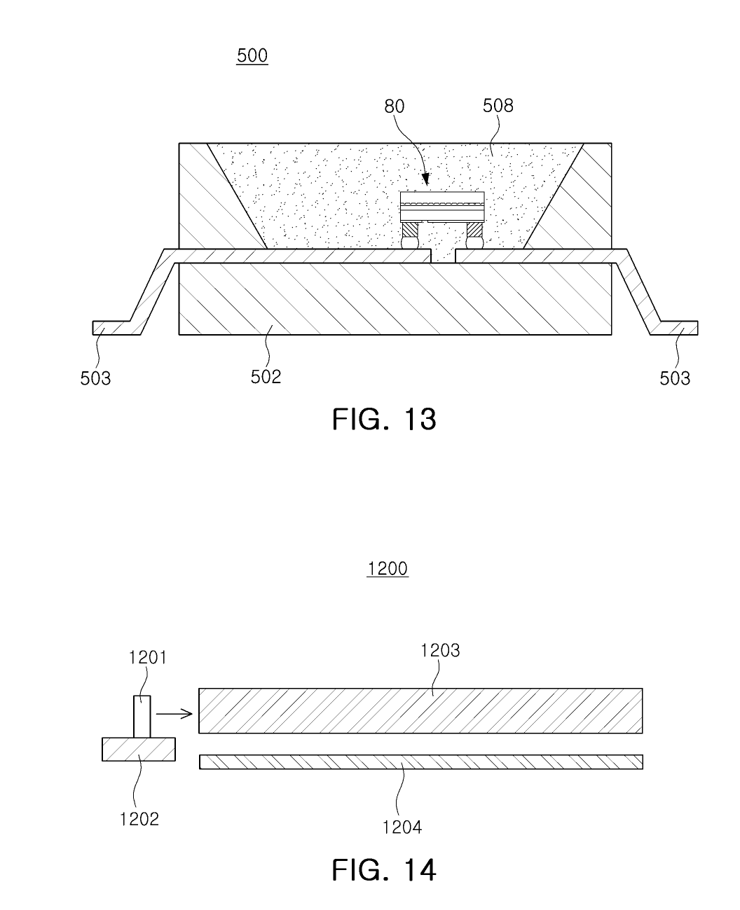

FIG. 13 is a cross-sectional view illustrating a package 500 employing the semiconductor light emitting device 80 illustrated in FIG. 8.

The semiconductor light emitting device package 500 illustrated in FIG. 13 may include the semiconductor light emitting device 80 illustrated in FIG. 8, a package body 502, and a pair of lead frames 503.

The semiconductor light emitting device 80 may be disposed on the lead frames 503, and thus respective electrode pads of the semiconductor light emitting device 80 may be electrically connected to the lead frames 503 in a flip chip bonding manner. If necessary, the semiconductor light emitting device 80 may be disposed on the package body 502, e.g., in a different portion except that of the lead frames 503. In addition, the package body 502 may have a groove portion having a cup shape such that light reflection efficiency may be increased, and an encapsulant 508 formed of a light transmitting material may be formed in the groove portion to encapsulate the semiconductor light emitting device 80.

The encapsulants 408 and 508 may contain a wavelength converting material, such as a phosphor and/or a quantum dot if necessary. The wavelength converting material may be formed by using various kinds of materials, such as a phosphor and/or a quantum dot.

A phosphor may have the following formulae and colors: yellow and green Y₃Al₅O₁₂:Ce, yellow and green Tb₃Al₅O₁₂:Ce, and yellow and green Lu₃Al₅O₁₂:Ce (oxide-based); yellow and green (Ba,Sr)₂SiO₄:Eu and yellow and orange (Ba,Sr)₃SiO₅:Ce (silicate-based); green β-SiAlON:Eu, yellow La₃Si₆N₁₁:Ce, orange α-SiAlON:Eu, red CaAlSiN₃:Eu, red Sr₂Si₅N₈:Eu, red SrSiAl₄N₇:Eu, and red SrLiAl₃N₄:Eu (nitride-based), Ln₄₋ₓ(Eu_{z}M_{1-z})ₓSi_{12-y}Al_{y}O_{3+x+y}N_{18-x-y} (0.5≦x≦3, 0<z≦0.3, 0<y≦4)—Formula (1), in which Ln may be at least one kind of element selected from the group consisting of group Ma elements and rare earth elements, and M may be at least one type of element selected from the group consisting of Ca, Ba, Sr and Mg; and KSF-based red K₂SiF₆:Mn₄⁺, KSF-based red K₂TiF₆:Mn₄⁺, KSF-based red NaYF₄:Mn₄⁺, and KSF-based red NaGdF₄:Mn₄⁺(fluoride-based).

In addition, a quantum dot (QD) may be used to replace a phosphor or to be mixed with a phosphor, as a wavelength converting material. The QD may implement various colors according to sizes thereof, and for instance, when used as a phosphor substitute, the QD may be employed as a red or green phosphor. In the case of using a QD, a relatively narrow half width (e.g., about 35 nm) may be implemented.

The wavelength converting material may be implemented in the form contained in an encapsulant. On the other hand, the wavelength converting material may be previously manufactured in the form of a film and may be attached to a surface of an optical structure, such as a semiconductor light emitting device or a light guide plate. In this case, the wavelength converting material may be readily applied to a desired portion of a structure having a uniform thickness.

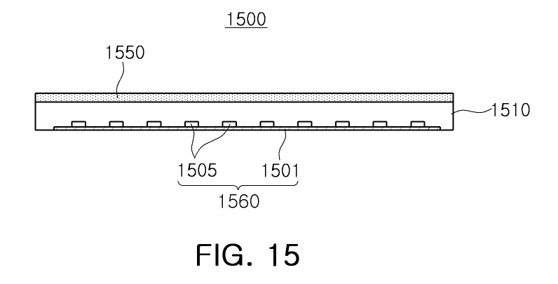

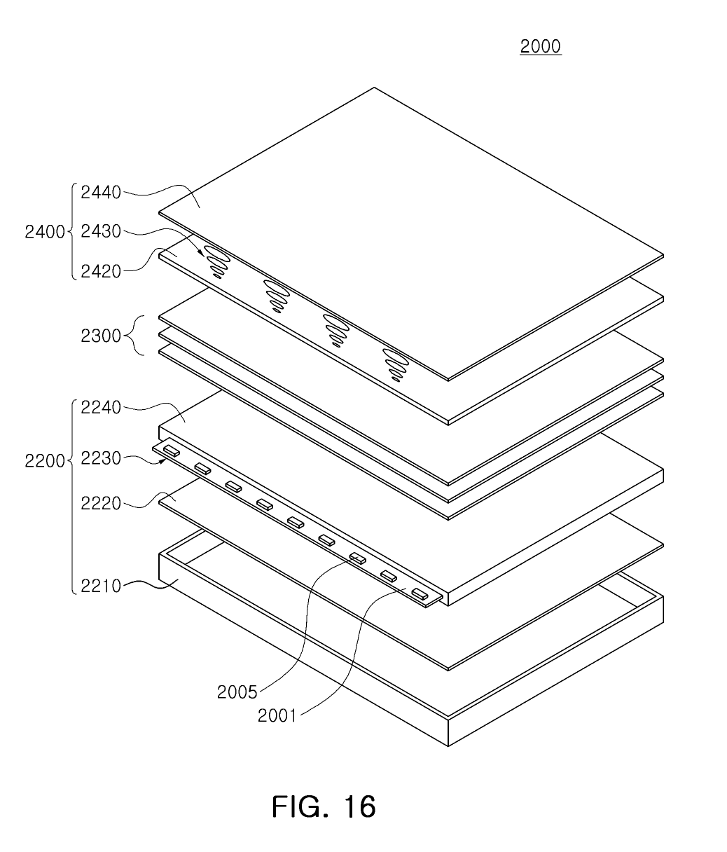

The wavelength converting material may be advantageously used in various light source devices, such as a backlight unit, a display device or a lighting system. FIGS. 14 and 15 are cross-sectional views illustrating backlight units according to various exemplary embodiments, and FIG. 16 is an exploded perspective view illustrating a display device according to an exemplary embodiment.

Referring to FIG. 14, a backlight unit 1200 may include a light guide plate 1203, and a circuit board 1202 disposed at a surface of the light guide plate 1203 and having a plurality of light sources 1201 mounted thereon. A reflector 1204 may be disposed below the light guide plate 1203 of the backlight unit 1200.

The light sources 1201 may radiate light to a surface of the light guide plate 1203, and the light may be incident on an inside of the light guide plate 1203 to be reflected to an upper portion of the light guide plate 1203. The backlight device according to the illustrated exemplary embodiment may be also referred to as “edge-type backlight unit”. The light source 1201 may include the aforementioned semiconductor light emitting device or semiconductor light emitting device package including the same together with a wavelength converting material. For example, the light source 1201 may be the semiconductor light emitting device packages 400 and 500.

Referring to FIG. 15, a backlight unit 1500 as a direct type backlight unit may include a wavelength converter 1550, a light source module 1560 arranged below the wavelength converter 1550, and a bottom case 1510 accommodating the light source module 1510. The light source module 1560 may also include a printed circuit board (PCB) 1501 and a plurality of light sources 1505 disposed on an upper surface of the PCB 1501. The light source 1505 may be the aforementioned semiconductor light emitting device or semiconductor light emitting device package including the same. The light source may not be used with a wavelength converting material.

The wavelength converter 1550 may be properly selected to emit white light according to wavelengths of the light source 1505. The wavelength converter 1550 may be manufactured as a separate film, or may be provided in the form of being integrated with another optical element, such as a separate light diffusion plate. As such, according to an exemplary embodiment, the wavelength converter 1550 may be spaced apart from the light source 1505, thereby reducing deterioration of reliability of the wavelength converter 1550 caused by heat emitted by the light source 1505.

FIG. 16 is a schematic exploded perspective view of a display device according to an exemplary embodiment.

Referring to FIG. 16, a display device 2000 may include a backlight unit 2200, optical sheets 2300, and an image display panel 2400 such as a liquid crystal panel.

The backlight unit 2200 may include a bottom case 2210, a reflector 2220, a light guide plate 2240, and a light source module 2230 provided on at least one surface of the light guide plate 2240. The light source module 2230 may include a printed circuit board (PCB) 2001 and light sources 2005, and the light sources 2005 may be the aforementioned semiconductor light emitting device or semiconductor light emitting device package including the same. The light sources 2005 may be a side view type light emitting device disposed on a surface adjacent to a light emitting surface. According to an exemplary embodiment, the backlight unit 2200 may be replaced by one of the backlight units 1200 and 1500 respectively illustrated in FIGS. 14 and 15.

The optical sheets 2300 may be disposed between the light guide plate 2240 and the image display panel 2400, and may include various kinds of sheets, such as a diffusion sheet, a prism sheet or a protection sheet.

The image display panel 2400 may display an image using light emitted through the optical sheets 2300. The image display panel 2400 may include an array substrate 2420, a liquid crystal layer 2430, and a color filter substrate 2440. The array substrate 2420 may include pixel electrodes disposed in matrix form, thin film transistors applying a driving voltage to the pixel electrodes, and signal lines operating the thin film transistors. The color filter substrate 2440 may include a transparent substrate, a color filter, and a common electrode. The color filter may include filters for selectively passing light having a certain wavelength of white light emitted by the backlight unit 2200. The liquid crystal layer 2430 may be re-arranged by an electric field generated between the pixel electrodes and the common electrode to adjust light transmittance. Light with adjusted light transmittance may be projected to display an image by passing through the color filter of the color filter substrate 2440. The image display panel 2400 may further include a driving circuit unit processing an image signal.

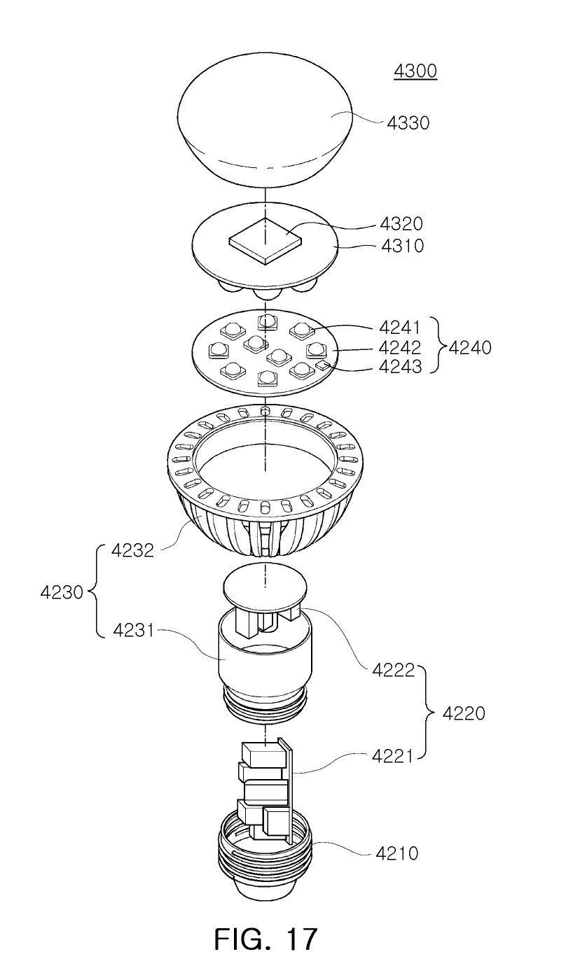

FIG. 17 is an exploded perspective view of a light emitting diode (LED) lamp employing a semiconductor light emitting device according to an exemplary embodiment.

Referring to FIG. 17, a lighting device 4300 may include a socket 4210, a power supply 4220, a heat dissipation portion 4230, and a light source module 4240. According to exemplary embodiment, the light source module 4240 may include a light emitting device array, and the power supply 4220 may include a light emitting device driver.

The socket 4210 may be configured to replace that of a conventional lighting device. Power supplied to the lighting device 4200 may be applied through the socket 4210. As illustrated in FIG. 17, the power supply 4220 may be separately assembled with a first power supply unit 4221 and a second power supply unit 4222. The heat dissipation portion 4230 may include an internal heat dissipation portion 4231 and an external heat dissipation portion 4232. The internal heat dissipation portion 4231 may be directly connected to the light source module 4240 and/or the power supply 4220. This connection may allow heat to transfer to the external heat dissipation portion 4232.

The light source module 4240 may receive power from the power supply 4220 to emit light to an optical portion 4330. The light source module 4240 may include light sources 4241, a circuit board 4242, and a controller 4243, and the controller 4243 may store driving information of the light sources 4241. The light sources 4241 may be the aforementioned semiconductor light emitting device or semiconductor light emitting device package including the same.

A reflector 4310 may be disposed above the light source module 4240, and may reduce glare by evenly spreading light emitted by the light sources 4241 to a side and a rear of the reflector 4310. In addition, a communications module 4320 may be disposed on an upper portion of the reflector 4310, and may perform home network communications. For example, the communications module 4320 may be a wireless communications module using Zigbee™, Wi-Fi, or Li-Fi, and may control on/off functions and brightness of a lighting device installed in and around the home through a smartphone or wireless controller. Further, use of a Li-Fi communications module using a visible light wavelength of the lighting device installed in and around the home may control electronic devices, such as a TV, a refrigerator, an air-conditioner, a door lock, and a vehicle ignition, and systems in and around the home. The reflector 4310 and the communications module 4320 may be covered with a cover 4330.

As set forth above, according to exemplary embodiments, placing the second finger electrodes along with the first finger electrodes into the trenches may reduce optical loss caused by the electrodes. In addition, removal of a portion of the active layer that does not function as an effective light emitting region below the second finger electrodes may improve light emitting efficiency in another effective region of the active layer.

While exemplary embodiments have been shown and described above, it will be apparent to those skilled in the art that modifications and variations could be made without departing from the scope of the present disclosure as defined by the appended claims.

1. A semiconductor light emitting device comprising:
a semiconductor laminate comprising a first conductive semiconductor layer, a second conductive semiconductor layer, an active layer between the first conductive semiconductor layer and the second conductive semiconductor layer, and a first trench and a second trench penetrating through the second conductive semiconductor layer and the active layer to first and second portions of the first conductive semiconductor layer, respectively;
a first finger electrode disposed on the first portion of the first conductive semiconductor layer in the first trench;
an insulating layer disposed on an internal surface of the second trench; and
a second finger electrode disposed on the insulating layer in the second trench and electrically connected to the second conductive semiconductor layer.

2. The semiconductor light emitting device of claim 1, further comprising a current spreading layer disposed on the second conductive semiconductor layer and electrically connected to the second finger electrode.

3. The semiconductor light emitting device of claim 2, wherein the current spreading layer extends into the second trench along an upper surface of the insulating layer.

4. The semiconductor light emitting device of claim 3, wherein the second finger electrode is disposed on a portion of the current spreading layer in the second trench.

5. The semiconductor light emitting device of claim 1, wherein the first and second trenches have substantially the same depth.

6. The semiconductor light emitting device of claim 1, wherein the second trench comprises a plurality of trenches arranged in a first direction.

7. The semiconductor light emitting device of claim 6, wherein the second finger electrode comprises a curved structure.

8. The semiconductor light emitting device of claim 1, wherein the insulating layer comprises a distributed bragg reflector (DBR) multi-layer film.

9. The semiconductor light emitting device of claim 1, further comprising an additional insulating layer on an internal side wall of the first trench.

10. The semiconductor light emitting device of claim 2, wherein the current spreading layer is substantially disposed on an entire region of an upper surface of the second conductive semiconductor layer.

11. The semiconductor light emitting device of claim 2, wherein the current spreading layer comprises a transparent electrode layer.

12. The semiconductor light emitting device of claim 11, wherein the current spreading layer contains at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO, 0≦x≦1).

13. The semiconductor light emitting device of claim 1, further comprising a third finger electrode.

14. The semiconductor light emitting device of claim 1, further comprising a first electrode pad electrically connected to the first finger electrode and a second electrode pad electrically connected to the second finger electrode.

15. The semiconductor light emitting device of claim 14, further comprising an insulating portion covering a surface of the semiconductor laminate on which the first and second finger electrodes are disposed, the insulating portion comprising a first via connected to the first finger electrode and a second via connected to the second finger electrode,
wherein the first and second electrode pads are disposed on the insulating portion and the first electrode pad is connected to the first finger electrode through the first via, and the second electrode pad is connected to the second finger electrode through the second via.

16. A semiconductor light emitting device comprising:
a semiconductor laminate comprising a first conductive semiconductor layer, a second conductive semiconductor layer, an active layer between the first conductive semiconductor layer and the second conductive semiconductor layer, and a first trench and a second trench penetrating through the second conductive semiconductor layer and the active layer to first and second portions of the first conductive semiconductor layer, respectively;
a first insulating layer disposed on an internal side wall of the first trench;
a first finger electrode disposed on the first portion of the first conductive semiconductor layer in the first trench;
a second insulating layer disposed on an internal surface of the second trench;
a current spreading layer disposed on the second conductive semiconductor layer and extending into the second trench along the second insulating layer; and
a second finger electrode disposed on a portion of the current spreading layer in the second trench.

17. The semiconductor light emitting device of claim 16, further comprising a first electrode pad electrically connected to the first finger electrode and a second electrode pad electrically connected to the second finger electrode,
wherein the first electrode pad is disposed on the portion of the first conductive semiconductor layer in the first trench, and the second electrode pad is disposed on the second conductive semiconductor layer.

18. The semiconductor light emitting device of claim 17, further comprising an additional insulating layer disposed between the second electrode pad and the second conductive semiconductor layer.

19.-22. (canceled)

23. A semiconductor light emitting device comprising:
a first conductive semiconductor layer, a second conductive semiconductor layer, an active layer between the first conductive semiconductor layer and the second conductive semiconductor layer, a plurality of first trenches and a plurality of second trenches penetrating through the second conductive semiconductor layer and the active layer to a plurality of first portions and a plurality of second portions of the first conductive semiconductor layer, respectively;
a plurality of first finger electrodes respectively disposed on the plurality of first portions within the plurality of first trenches;
an insulating layer disposed to cover the plurality of second portions within the plurality of second trenches; and
a plurality of second finger electrodes respectively disposed on the insulating layer.

24. The semiconductor light emitting device of claim 23, further comprising a current spreading layer disposed on the second conductive semiconductor layer and electrically connected to one of the plurality of second finger electrodes.

25. (canceled)
